(19) United States
(12) Patent Application Publication
(10) Pub. No.: US 2023/0349036 A1
(43) Pub. Date: Nov. 2, 2023

(54) SUBSTRATE PROCESSING METHOD AND SUBSTRATE PROCESSING APPARATUS

(71) Applicant: Tokyo Electron Limited, Tokyo (JP)

(72) Inventors: Masato SHINADA, Tokyo (JP); Junichi TAKEI, Yamanashi (JP); Naoki TAKAHASHI, Yamanashi (JP)

(21) Appl. No.: 18/299,904

(22) Filed: Apr. 13, 2023

(30) Foreign Application Priority Data
Apr. 27, 2022 (JP) 2022-073737

(51) Int. Cl. C23C 14/56; C23C 16/44; C23C 16/46

(52) U.S. Cl. CPC C23C 14/566; C23C 14/568; C23C 16/4412; C23C 16/46

(57) ABSTRACT

With respect to a substrate processing method performed by a substrate processing apparatus including a vacuum chamber, a stage disposed in the vacuum chamber and including a heater, a gas supply that supplies a gas into the vacuum chamber, an exhaust device that exhaust the gas in the vacuum chamber, and an electrode installed in the vacuum chamber, the electrode being connected to the stage and applying a voltage to the heater, the substrate processing method includes performing a discharge countermeasure process including lowering the voltage applied to the heater while a pressure in the vacuum chamber is within a discharge pressure range, the discharge pressure range being determined based on Paschen's law as a pressure range in which discharge occurs in the vacuum chamber, and applying the voltage to the heater in response to determining that the pressure in the vacuum chamber is out of the discharge pressure range.

### CROSS-REFERENCE TO RELATED APPLICATIONS

This patent application is based on and claims priority to Japanese Patent Application No. 2022-073737 filed on Apr. 27, 2022, the entire contents of which are incorporated herein by reference.

### TECHNICAL FIELD

The present disclosure relates to a substrate processing method and a substrate processing apparatus.

### BACKGROUND

For example, Patent Document 1 discloses a degassing apparatus that removes impurities on a surface of a substrate by heat. The degassing apparatus adjusts the pressure in a vacuum chamber to a high vacuum, mounts the substrate on a heatable stage, and heats the substrate, thereby blowing off moisture and gas adhering to the substrate and removing impurities from the surface of the substrate.

### RELATED ART DOCUMENT

### Patent Document

[Patent Document 1] Japanese Laid-open Patent Application Publication No. 2002-252271

### SUMMARY

According to one aspect of the present disclosure, with respect to a substrate processing method performed by a substrate processing apparatus including a vacuum chamber, a stage disposed in the vacuum chamber, the stage including a heater, a gas supply configured to supply a gas into the vacuum chamber, an exhaust device configured to exhaust the gas in the vacuum chamber, and an electrode installed in the vacuum chamber, the electrode being connected to the stage and applying a voltage to the heater, the substrate processing method includes performing a discharge countermeasure process. The discharge countermeasure process includes lowering the voltage applied to the heater while a pressure in the vacuum chamber is within a discharge pressure range, the discharge pressure range being determined based on Paschen's law as a pressure range in which discharge occurs in the vacuum chamber, and applying the voltage to the heater in response to determining that the pressure in the vacuum chamber is out of the discharge pressure range.

### BRIEF DESCRIPTION OF THE DRAWINGS

FIG. 1A is a diagram illustrating a configuration example and an operation example of a substrate processing apparatus according to an embodiment;

FIG. 1B is a diagram illustrating the configuration example and the operation example of the substrate processing apparatus according to the embodiment;

FIG. 1C is a diagram illustrating the configuration example and the operation example of the substrate processing apparatus according to the embodiment;

FIG. 1D is a diagram illustrating the configuration example and the operation example of the substrate processing apparatus according to the embodiment;

FIG. 2A is a diagram illustrating an operation example of the substrate processing apparatus subsequent to FIGS. 1A to 1D;

FIG. 2B is a diagram illustrating the operation example of the substrate processing apparatus subsequent to FIGS. 1A to 1D;

FIG. 2C is a diagram illustrating the operation example of the substrate processing apparatus subsequent to FIGS. 1A to 1D;

FIG. 2D is a diagram illustrating the operation example of the substrate processing apparatus subsequent to FIGS. 1A to 1D;

FIG. 3 is a graph for depicting Paschen's law;

FIG. 4 is a flowchart illustrating an example of a substrate processing method according to the embodiment; and

FIG. 5 is a diagram illustrating an example of a substrate processing system according to the embodiment.

### DETAILED DESCRIPTION OF EMBODIMENTS

In the following, an embodiment of the present disclosure will be described with reference to the drawings. In the drawings, the same components are referenced by the same reference numerals, and duplicated description may be omitted.

In the present specification, in directions such as parallel, perpendicular, orthogonal, horizontal, vertical, up-and-down, and left-and-right, deviations are allowed to such an extent that the effects of the embodiment are not impaired. A shape of a corner is not limited to a right angle and may be rounded in an arcuate shape. Parallel, perpendicular, orthogonal, horizontal, vertical, circular, and coincident may include substantially parallel, substantially perpendicular, substantially orthogonal, substantially horizontal, substantially vertical, substantially circular, and substantially coincident.

### CONFIGURATION EXAMPLE OF A SUBSTRATE PROCESSING APPARATUS

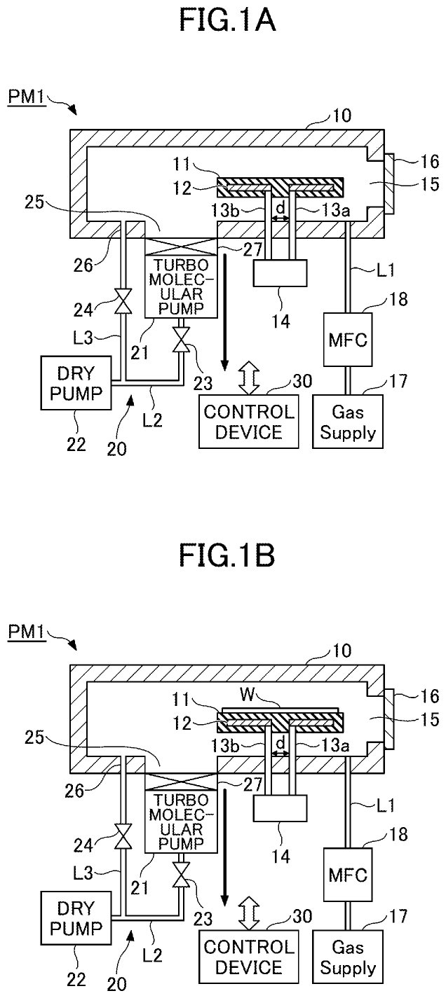

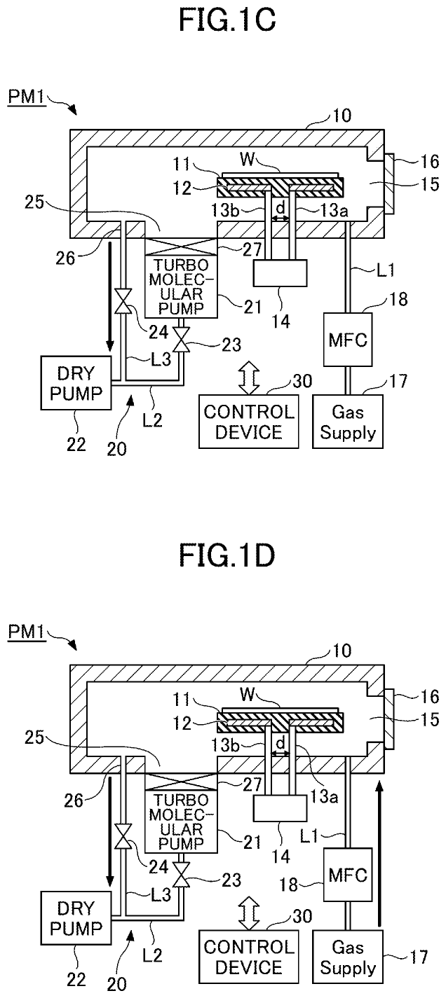

A configuration example of a substrate processing apparatus according to the embodiment will be described with reference to FIGS. 1A to 1D. FIGS. 1A to 1D are diagrams illustrating the configuration example and an operation example of a substrate processing apparatus PM1 according to the embodiment. In FIGS. 1A to 1D, as an example of the substrate processing apparatus PM1, a configuration example of a degassing apparatus that removes impurities on a surface of a substrate by heat will be described.

As illustrated in FIG. 1A, the substrate processing apparatus PM1 includes a vacuum chamber 10, a stage 11, a gas supply 17, and an exhaust device 20. The vacuum chamber 10 has a transfer port 15 on a side wall of the vacuum chamber 10, and the transfer port 15 is provided with a gate valve 16 that opens and closes the transfer port 15. The stage 11 is disposed inside the vacuum chamber 10. The upper surface of the stage 11 serves as a mounting surface on which a substrate W is mounted. The substrate is carried in the vacuum chamber 10 through the transfer port 15 by the gate valve 16 being opened, and is mounted on the mounting surface of the stage 11. After the substrate W is carried in, the gate valve 16 is closed. The stage 11 is formed of a dielectric material such as ceramics, and includes a metal heater 12 inside the stage 11. Although illustration of a specific structure of the heater 12 is omitted, the heater 12 may have any shape such as a spiral shape. As illustrated in FIG. 1B and the like, the substrate W mounted on the stage 11 is heated by the heater 12. The mechanism for heating the substrate W may be provided not only inside the stage 11 but also in any part of the vacuum chamber 10.

In the vacuum chamber 10, electrodes 13a and 13b are installed such that the electrodes 13a and 13b are spaced apart with a distance d. The electrodes 13a and 13b penetrate the bottom wall of the vacuum chamber 10, and the electrodes 13a and 13b are disposed in the vacuum chamber 10 and connected to the stage 11. Ends of the electrodes 13a and 13b are connected to an input end and an output end of the heater 12, respectively. The electrodes 13a and 13b are power supply lines for applying a voltage from a power supply 14 disposed outside the vacuum chamber 10 to the heater 12, and the peripheries of the electrodes 13a and 13b are insulated. The electrodes 13a and 13b are also collectively referred to as an electrode 13.

The gas supply 17 supplies an inert gas into the vacuum chamber 10 from a gas supplying line L1 via a flow rate controller 18. The flow rate controller 18 may include, for example, a mass flow controller or a pressure control type flow rate controller.

An example of the inert gas supplied into the vacuum chamber 10 by the gas supply 17 is an argon gas. In this case, the gas atmosphere in the vacuum chamber 10 is an argon gas atmosphere. In the present specification, the inert gas may include a nitrogen gas, and the gas supply 17 may supply a nitrogen gas into the vacuum chamber 10 as another example of the inert gas. In this case, the gas atmosphere in the vacuum chamber 10 is a nitrogen gas atmosphere. The gas supply 17 may switch between the argon gas and the nitrogen gas to be supplied into the vacuum chamber 10 at a timing to be described later, so that the gas atmosphere in the vacuum chamber 10 becomes an atmosphere of either the argon gas or the nitrogen gas, or an atmosphere in which these gases are mixed.

The exhaust device 20 exhausts the gas in the vacuum chamber 10 to bring the inside of the vacuum chamber 10 into a vacuum state. The exhaust device 20 is connected to, for example, a gas discharge port 25 provided at the bottom of the vacuum chamber 10. The exhaust device 20 may include a pressure adjusting valve 27 and a vacuum pump. The pressure adjusting valve 27 is connected to the gas discharge port 25, and the pressure in the vacuum chamber 10 is adjusted by the pressure adjusting valve 27. The vacuum pump includes a dry pump 22 and a turbo molecular pump 21. The turbo molecular pump 21 is disposed on the downstream side of the pressure adjusting valve 27, and the dry pump 22 is disposed on the downstream side of the turbo molecular pump 21. The turbo molecular pump 21 is connected to the dry pump 22 via an exhaust line L2. Additionally, the dry pump 22 is connected to a gas discharge port 26 provided at the bottom of the vacuum chamber 10 via an exhaust line L3.

An opening/closing valve 23 is provided in the exhaust line L2, and an opening/closing valve 24 is provided in the exhaust line L3. First, the opening/closing valve 24 is opened, the opening/closing valve 23 is closed, and the inside of the vacuum chamber 10 is exhausted from the gas discharge port 26 by the dry pump 22 (rough pumping). Subsequently, the opening/closing valve 23 is opened, the opening/closing valve 24 is closed, and the inside of the vacuum chamber 10 is further exhausted by the turbo molecular pump 21, using the turbo molecular pump 21 having a smaller exhaust amount than the dry pump 22 (vacuum pumping). Thereby, the vacuum chamber 10 can be brought into a high vacuum state. Subsequently, during a degassing process, the opening/closing valve 24 is opened, the opening/closing valve 23 is closed, and the inside of the vacuum chamber 10 is vacuumed from the gas discharge port 26 by the dry pump 22. After the degassing process, the opening/closing valve 23 is opened again, the opening/closing valve 24 is closed, and the inside of the vacuum chamber 10 is exhausted from the gas discharge port 25 by the turbo molecular pump 21 and the dry pump 22.

A control device 30 processes computer-executable instructions that cause the substrate processing apparatus PM1 to perform various steps described in the present disclosure. The control device 30 may be configured to control the elements of the substrate processing apparatus PM1 to perform the various steps described herein. In the embodiment, part or the entirety of the control device 30 may be included in the substrate processing apparatus PM1. The control device 30 may include a processor, a storage unit, and a communication interface. The control device 30 is implemented by, for example, a computer. The processor may be configured to perform various control operations by reading a program from the storage unit and executing the read program. The program may be stored in the storage unit in advance, or may be acquired via a medium when necessary. The acquired program is stored in the storage unit, and is read from the storage unit and executed by the processor. The medium may be various computer-readable storage media or may be a communication line connected to the communication interface. The processor may be a central processing unit (CPU). The storage unit may include a random access memory (RAM), a read only memory (ROM), a hard disk drive (HDD), a solid state drive (SSD), or a combination thereof. The communication interface may communicate with the substrate processing apparatus PM1 via a communication line such as a local area network (LAN).

In the substrate processing apparatus PM1, the substrate W is carried into the vacuum chamber 10, is mounted on the stage 11, and the substrate W is heated by the heater 12. Additionally, when the substrate W is carried into the vacuum chamber 10, the inert gas is supplied into the vacuum chamber 10. Thereby, the inside of the vacuum chamber 10 is pressurized, moisture and organic substances on the surface of the substrate W heated in the atmosphere of the inert gas are blown off, and impurities are removed from the surface of the substrate W. The processing of removing impurities from the surface of the substrate W by heating the substrate W is also referred to as the “degassing process”.

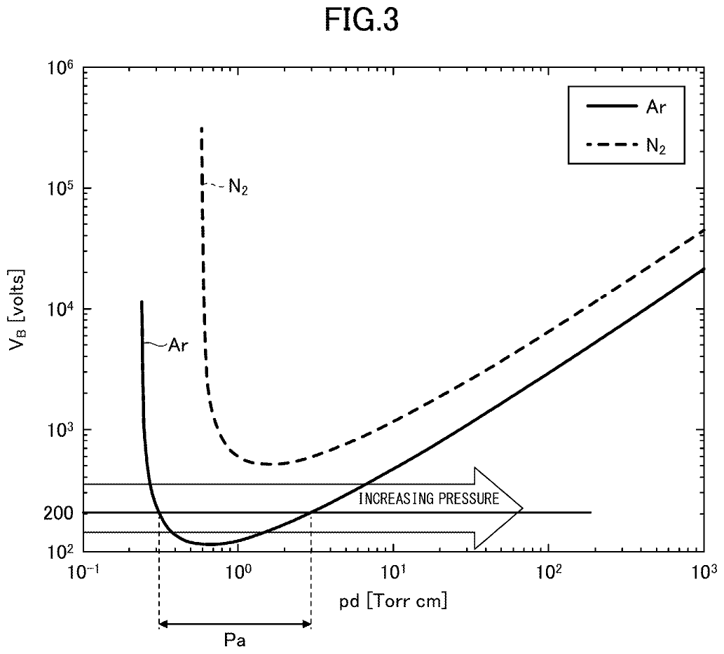

The temperature of the substrate W is not easily increased by only the radiant heat in the vacuum chamber 10. Then, the vacuum chamber 10 is filled with the inert gas and the inside of the vacuum chamber 10 is pressurized to a high pressure to raise the temperature inside the vacuum chamber 10, thereby heating the substrate W. The inert gas used when the inside of the vacuum chamber 10 is pressurized to a high pressure is the argon gas or the nitrogen gas. In the processing of supplying the argon gas into the vacuum chamber 10 and increasing the pressure therein, where the pressure in the vacuum chamber 10 is “p” and the voltage applied to the heater 12 is “V_{B}”, discharge occurs based on Paschen's law illustrated in FIG. 3. The horizontal axis represents a product pd [Torr cm] of a pressure p inside the vacuum chamber 10 and a distance d between the electrodes 13a and 13b, and the vertical axis represents a voltage V_{B} [volts (V)] applied to the heater 12. The distance d between the electrodes 13a and 13b (the interelectrode distance) is constant.

According to Paschen's law, in the process of supplying a gas into the vacuum chamber 10 to increase or decrease the pressure, while the pressure p inside the vacuum chamber 10 is passing through a region where discharge occurs, abnormal discharge (abnormality in the current value) occurs between the electrodes 13a and 13b. For example, a case where the voltage V_{B} applied to the heater 12 indicated in the vertical axis of FIG. 3 is 200 [V] and the argon gas is supplied into the vacuum chamber 10 will be described as an example. Here, for example, in the pressure increasing process, a region in which discharge occurs between the electrodes 13 in the vacuum chamber 10 (hereinafter referred to as a “discharge pressure range”) is present. The discharge pressure range when the voltage V_{B} is 200 [V] is indicated by the arrow and the letter “Pa” indicating the discharge pressure in FIG. 3. Discharge is generated between the electrodes 13 in the vacuum chamber 10 in the discharge pressure range not only in the process of increasing the pressure in the vacuum chamber 10 but also in the process of decreasing the pressure in the vacuum chamber 10.

When discharge occurs between the electrodes 13, a problem in the operation of the substrate processing apparatus PM1 arises. As one example of this problem, a dielectric breakdown occurs in the electrodes 13, an overcurrent flows through the electrodes 13 (abnormal discharge), and consequently a breaker operates to protect the power supply, thereby causing the power supply 14 to trip (a power outage). As a result, the substrate W cannot be heated, and the throughput of the degassing process decreases. Therefore, it is important to avoid tripping of the power supply 14 by taking a countermeasure.

Here, in order to prevent the abnormal discharge, the application of the voltage to the heater 12 is stopped within the discharge pressure range in the process of increasing the pressure in the vacuum chamber 10 and in the process of decreasing the pressure in the vacuum chamber 10. Then, automatic control is performed to automatically start the application of the voltage to the heater 12 after passing through the discharge pressure range.

By providing a sequence controlling the steps of performing the discharge countermeasure process described above, the degassing process can be performed by heating the substrate W while preventing burnout of the electrodes 13 due to abnormal discharge between the electrodes 13. In the following, a substrate processing method will be described with reference to an example in which the argon gas is supplied into the vacuum chamber 10 as the inert gas when the substrate W is carried in.

### Substrate Processing Method

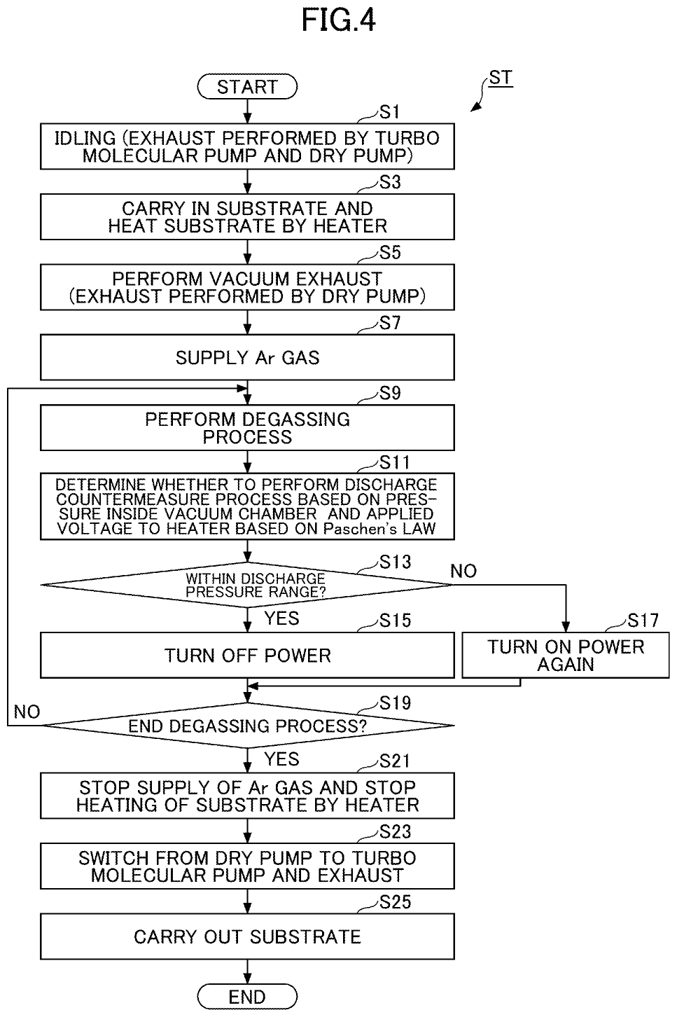

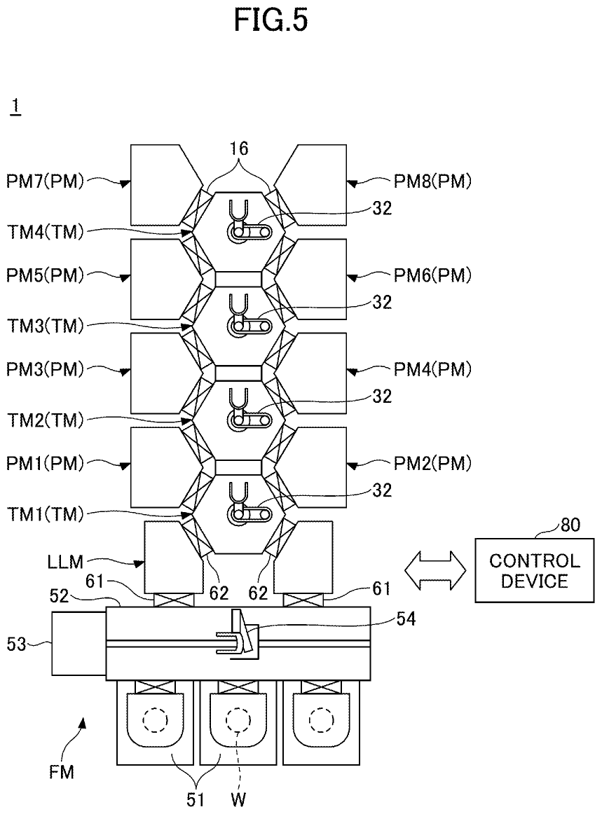

The substrate processing method performed by the substrate processing apparatus PM1 will be described with reference to FIGS. 1A to 4. FIGS. 1A to 3 are used to describe an operation example of the substrate processing apparatus PM1 during execution of a substrate processing method ST. FIG. 4 is a flowchart illustrating an example of the substrate processing method ST according to the embodiment. The substrate processing method ST illustrated in FIG. 4 includes the discharge countermeasure process and each processing is automatically controlled by a control device 30.

When the substrate processing method ST of FIG. 4 is started, in step S1, the control device 30 controls the exhaust performed by the exhaust device 20 (the turbo molecular pump 21 and the dry pump 22) while the substrate processing apparatus PM1 is idle. At this time, as illustrated in FIG. 1A, the substrate processing apparatus PM1 is in an idle state, and the turbo molecular pump 21 and the dry pump 22 exhaust the inside of the vacuum chamber 10 through the gas discharge port 25 to bring the inside of the vacuum chamber 10 into a reduced pressure state.

In step S3, the control device 30 opens the gate valve 16, carries the substrate W into the vacuum chamber 10 from the transfer port 15, and mounts the substrate W on the mounting surface of the stage 11. Further, the control device 30 applies a voltage from the power supply 14 to the heater 12 to heat the substrate W. After the substrate W is carried into the vacuum chamber 10, the control device 30 closes the gate valve 16. At this time, as illustrated in FIG. 1B, the substrate W is carried into the vacuum chamber 10 and the substrate W is heated by the heater 12.

In step S5, the control device 30 switches from the turbo molecular pump 21 and the dry pump 22 to the dry pump 22, and controls the exhaust performed by the dry pump 22. At this time, as illustrated in FIG. 1C, the dry pump 22 exhausts the inside of the vacuum chamber 10 from the gas discharge port 26 to bring the inside of the vacuum chamber 10 into a vacuum state.

In step S7, the control device 30 supplies the argon gas from the gas supply 17 into the vacuum chamber 10 while continuing the exhaust by the dry pump 22. At this time, as illustrated in FIG. 1D, the exhaust by the dry pump 22 and the supply of the argon gas into the vacuum chamber 10 are performed. At this time, the pressure in the vacuum chamber 10, which has been in a high vacuum state, is increased by the supplied argon gas. At this time, in order to adjust the exhaust amount of the dry pump 22, the conductance of the exhaust line L3 or the output of the dry pump 22 may be adjusted.

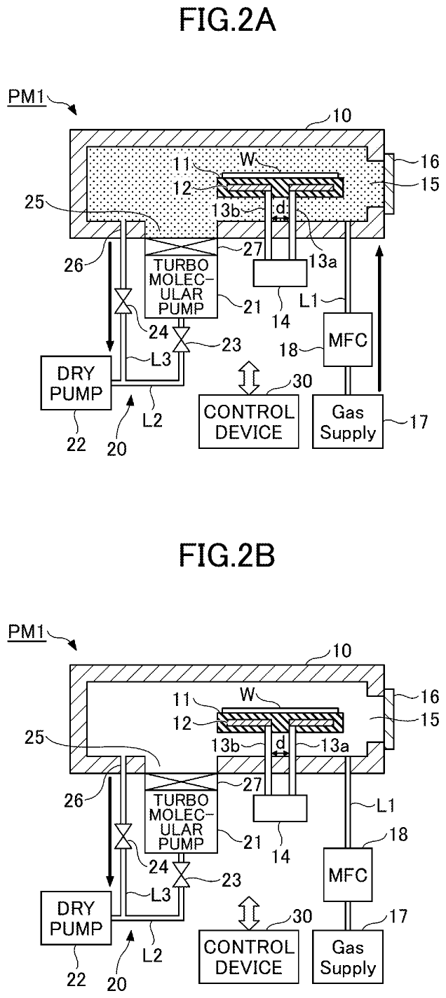

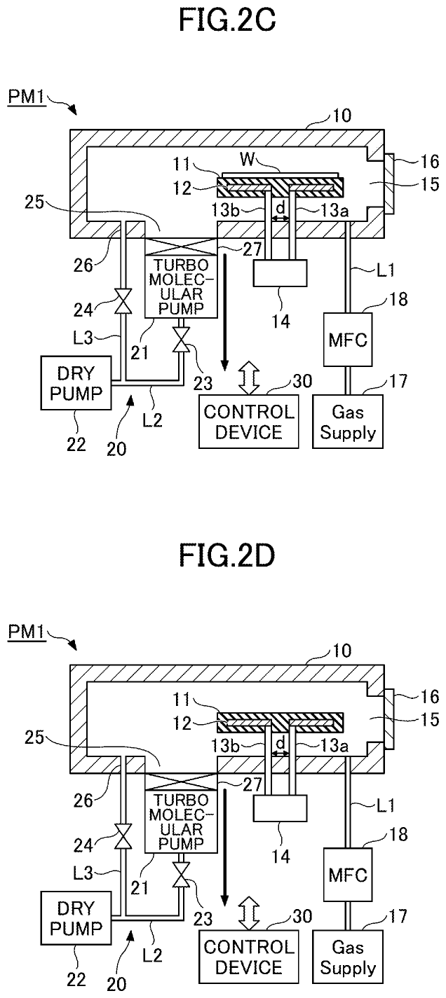

In step S9, the control device 30 heats the inside of the vacuum chamber 10 and the stage 11 by increasing the pressure in the vacuum chamber 10 and applying the voltage to the heater 12, thereby heating the substrate W and performing the degassing process. At this time, as illustrated in FIG. 2A, the inside of the vacuum chamber 10 and the heater 12 are heated. As a result, moisture, organic matter, and the like on the surface of the substrate W are blown off, so that impurities can be removed from the surface of the substrate W.

In step S11, the control device 30 determines whether to perform the discharge countermeasure process based on the pressure p inside the vacuum chamber 10 and the voltage VB applied to the heater 12, based on Paschen's law. When the argon gas is supplied into the vacuum chamber 10, it is determined to perform the discharge countermeasure process, based on Paschen's law illustrated in FIG. 3 by using the combination of the gas type, and the value of pd and the voltage V_{B} at this time.

As a result of the determination of performing the discharge countermeasure process, in step S13, when it is determined based on Paschen's law that the value of pd at the voltage V_{B} is within the discharge pressure range, the control device 30 proceeds to step S15 and turns off the power supply 14 of the heater 12. Thereby, the occurrence of abnormal discharge can be prevented.

For example, as illustrated in FIG. 3, while the voltage V_{B} applied to the heater 12 is 200 [V] and the pressure inside the vacuum chamber 10 is increased, the power supply 14 maintains the ON state while the value of pd is less than the range of the discharge pressure Pa with respect to the pressure p in the vacuum chamber 10. When the value of pd becomes within the range of the discharge pressure Pa after the pressure inside the vacuum chamber 10 is gradually increased, the power supply 14 is turned off and the voltage V_{B} applied from the power supply 14 to the heater 12 is set to 0V. The discharge pressure range is determined based on the voltage applied to the heater 12, the pressure p inside the vacuum chamber 10, and the gas type. The control device 30 performs step S13 with reference to the discharge pressure range preset based on Paschen's law for each combination of the voltage applied to the heater 12, the pressure inside the vacuum chamber 10, and the gas type.

When the control device 30 determines in step S13 that the value of pd is greater than the discharge pressure range after the pressure inside the vacuum chamber 10 is further increased, the control device 30 turns on the power supply 14 again in step S17.

Here, the processing of steps S11 to S17 may be performed immediately after the processing of step S7. Additionally, the processing of steps S11 to S17 is performed not only in the process of increasing the pressure inside the vacuum chamber 10 but also in the process of decreasing the pressure inside the vacuum chamber 10.

In step S19, the control device 30 determines whether to end the degassing process. While it is determined to continue the degassing process, the processing of steps S9 to S19 is performed.

When it is determined in step S19 that the degassing process is to be ended, the process proceeds to step S21, and the control device 30 stops the supply of the argon gas into the vacuum chamber 10 and stops the application of the voltage from the power supply 14 to the heater 12. Thereby, as illustrated in FIG. 2B, the supply of the argon gas is stopped, and the heating of the substrate W is stopped. The argon gas is exhausted from the inside of the vacuum chamber 10 by the dry pump 22.

In step S23, the control device 30 switches from the dry pump 22 to the turbo molecular pump 21 having a smaller exhaust amount, and exhausts the inside of the vacuum chamber 10 by the turbo molecular pump 21. Thereby, as illustrated in FIG. 2C, the argon gas is exhausted from the inside of the vacuum chamber 10 by the turbo molecular pump 21.

In step S25, the control device 30 opens the gate valve 16 and carries out the substrate W through the transfer port 15 after the degassing . After the substrate W is carried out, the 10 control device 30 closes the gate valve 16 and ends the present process. Thereby, as illustrated in FIG. 2D, the substrate processing apparatus PM1 remains in an idle state until the processing of the next substrate is started.

As described above, according to the substrate processing method of the present disclosure, the discharge countermeasure process including the following steps 1 and 2 is performed during the degassing process in the substrate processing apparatus PM1. In step 1, the application of the voltage to the heater 12 is stopped with reference to the discharge pressure range in which discharge occurs in the vacuum chamber 10 based on Paschen's law, while the pressure inside the vacuum chamber 10 is within the discharge pressure range. Step 2 is performed after performing step 1, and when the pressure inside the vacuum chamber 10 is out of the discharge pressure range, the application of the voltage to the heater 12 is started again.

By performing the discharge countermeasure process including steps 1 and 2, the occurrence of abnormal discharge due to the occurrence of dielectric breakdown between the electrodes 13 in the substrate processing apparatus PM1, in which the electrodes 13 supplying the voltage to the heater 12 are installed inside the vacuum chamber 10, can be prevented. Particularly, owing to step 1, abnormal discharge in the electrodes 13 connected to the stage 11 in the vacuum chamber 10 can be prevented. Additionally, temperature drop of the substrate W on the stage 11 can be suppressed owing to step 2.

The time during which the application of the voltage to the heater 12 is stopped in step 1 is approximately one second or less. Additionally, because the stage 11 is formed of ceramics or the like, the stage 11 has a heat capacity and has a function of holding heat. Therefore, temperature drop of the substrate W on the stage 11 caused by the stopping of the application of the voltage to the heater 12 is small, and the application of the voltage to the heater 12 is automatically started again immediately. Thereby, the substrate W can be heated in a short time by pressurizing the substrate W on the heater 12 to a high pressure while preventing abnormal discharge in the electrodes 13, and the degassing process can be performed.

### MODIFIED EXAMPLE 1

For example, in Modified Example 1, in step 1, while the pressure inside the vacuum chamber 10 is within the discharge pressure range, instead of stopping the application of the voltage to the heater 12, a voltage that is lower than the voltage applied immediately prior thereto and that is at a level at which abnormal discharge does not occur may be applied to the heater 12. The upper limit of the voltage that is lower than the voltage applied to the heater immediately prior thereto and that is at a level at which abnormal discharge does not occur may be 100V.

A case of using the argon gas illustrated in FIG. 3 will be described as an example. Within the discharge pressure range (Pa) when the voltage V_{B} is 200 [V], instead of stopping the application of the voltage to the heater 12, a voltage of 100 [V] is applied to the heater 12 as the voltage that is lower than the voltage applied to the heater 12 immediately prior thereto and that is a level at which abnormal discharge does not occur. In this case, as illustrated in FIG. 3, no matter which gas is supplied into the vacuum chamber 10, the abnormal discharge is not prevented based on Paschen's law. Further, in comparison with the case where the application of the voltage to the heater 12 is stopped, the temperature drop of the substrate W can be further reduced.

### MODIFIED EXAMPLE 2

For example, in Modified Example 2, the supply of the argon gas and the supply of the nitrogen gas may be switched in step 1 and step 2. That is, in Modified Example 2, in step 1, while the pressure inside the vacuum chamber 10 is within the discharge pressure range, instead of stopping the application of the voltage to the heater 12, the gas to be supplied into the vacuum chamber 10 is switched from the argon gas to the nitrogen gas, and the nitrogen gas is supplied into the vacuum chamber 10. Thereby, as illustrated in FIG. 3, in the discharge pressure range (Pa) in which abnormal discharge occurs when argon gas is used based on Paschen's law, the occurrence of abnormal discharge can be prevented from occurring in the electrodes 13 by supplying the nitrogen gas.

In step 2, when the pressure inside the vacuum chamber 10 is out of the discharge pressure range, the nitrogen gas is switched to the argon gas again and the argon gas is supplied into the vacuum chamber 10. Thereby, as illustrated in FIG. 3, the occurrence of abnormal discharge can be prevented without lowering the voltage V_{B} applied to the heater 12. Additionally, in comparison with the case where the application of the voltage to the heater 12 is stopped or the voltage applied to the heater 12 is lowered, temperature drop of the substrate W can be made smaller. Further, by supplying the nitrogen gas only when the pressure inside the vacuum chamber 10 is within the discharge pressure range, the time during which the substrate W is exposed to the nitrogen gas can be minimized.

Thereby, the generation of nitride such as the nitriding of the film on the substrate W can be minimized.

Here, when the generation of the nitride described above is not desired, it is more preferable to perform the discharge countermeasure process of the embodiment or Modified Example 1 than the discharge countermeasure process of Modified Example 2. That is, when the substrate W is carried into the vacuum chamber 10, it is preferable to supply the argon gas, which is an inert gas. This is because the argon gas is inert and does not react with the film formed on the substrate W, whereas the nitrogen gas reacts with the film on the substrate to nitride the film. However, the nitrogen gas may also be used. Additionally, a krypton gas may be used as the inert gas. Additionally, in the embodiment, Modified Example 1, and Modified Example 2, a mixture gas of the argon gas and the nitrogen gas may be supplied. The mixing ratio of both gases is determined in accordance with the film on the substrate W and the process.

### Substrate Processing System

An example of a substrate processing system including the substrate processing apparatus PM1 will be described with reference to FIG. 5. FIG. 5 is a diagram illustrating an example of a substrate processing system 1 according to the embodiment.

The substrate processing system 1 according to the embodiment is configured as a multi-chamber type having multiple process modules PM. The substrate processing system 1 is used in a process of manufacturing a semiconductor, sequentially transfers substrates to respective process modules PM by multiple transfer modules TM, and performs appropriate substrate processing in each of the process modules PM. Examples of the substrate processing performed by the process module PM include a degassing process, a film deposition process, an etching process, an asking process, a cleaning process, and the like.

In the substrate processing system 1, after the substrate W is carried in from an ambient air atmosphere to a vacuum atmosphere, the substrate processing of the substrate W is performed in each transfer module TM and each process module PM in the vacuum atmosphere, and after the substrate processing, the substrate W is carried out from the vacuum atmosphere to the ambient air atmosphere. Thus, the substrate processing system 1 includes a front module FM (for example, an equipment front end module (EFEM)) configured to transfer the substrate in the ambient air atmosphere, and a load lock module LLM configured to switch between the ambient air atmosphere and the vacuum atmosphere. Additionally, the substrate processing system 1 includes a control device 80 configured to control the front module FM, the load lock module LLM, each process module PM, and each transfer module TM.

The front module FM includes multiple load ports 51, a loader 52 adjacent to the respective load ports 51, and a positioning device 53 (an orienter) provided at a position adjacent to the loader 52. A front opening unified pod (FOUP) storing multiple substrates W after the previous manufacturing process (unprocessed substrates W) and an empty FOUP to store substrates W processed in the substrate processing system 1 are set in each of the load ports 51.

The loader 52 is formed in a rectangular box body having a cleaning space therein. The front module FM includes an atmospheric transfer device 54 inside the loader 52. The positioning device 53 cooperates with the atmospheric transfer device 54 to adjust a position of the substrate W taken out from the FOUP in the circumferential direction, a support orientation of the substrate W supported by the atmospheric transfer device 54, and the like.

The atmospheric transfer device 54 carries the substrate W positioned by the positioning device 53 into the load lock module LLM. Additionally, the atmospheric transfer device 54 carries out the substrate W from the load lock module LLM and accommodates the substrate W in the FOUP through the cleaning space in the loader 52.

Two load-lock modules LLM are provided between the front module FM and the transfer module TM. Between each of the load-lock modules LLM and the front module FM, a gate valve 61 for maintaining airtightness inside the load-lock module LLM is provided. Additionally, between each of the load lock modules LLM and the transfer module TM, a gate valve 62 for maintaining airtightness between the load lock module LLM and the transfer module TM is provided.

The load lock module LLM accommodates the substrate W carried in from the front module FM in the ambient air atmosphere and then lowers the pressure to the vacuum atmosphere, thereby enabling the substrate W to be transferred to the transfer module TM. Additionally, the load lock module LLM accommodates the substrate W carried in from the transfer module TM in the vacuum atmosphere, and then increases the pressure to the ambient air atmosphere, thereby enabling the substrate W to be transferred to the front module FM. Here, the substrate processing system 1 may include only one load lock module LLM.

In the substrate processing system 1 according to the present embodiment, multiple (four) transfer modules TM are installed side by side, and multiple (eight) process modules PM are installed at positions adjacent to the respective transfer modules TM. In the following, the multiple transfer modules TM are referred to as a first transfer module TM1, a second transfer module TM2, a third transfer module TM3, and a fourth transfer module

TM4 in the near side of the two load lock modules LLM to the far side of the two load lock modules LLM. The first transfer module TM1, the second transfer module TM2, the third transfer module TM3, and the fourth transfer module TM4 constitute a transfer module group linearly arranged along a direction orthogonal to the longitudinal direction of the loader 52.

Four process modules PM are installed on the left side of the transfer module group and four process modules PM are installed on the right side of the transfer module group so as to correspond to the four transfer modules TM. In the following, by using FIG. 5 as an example, the process modules PM installed on the left side of the respective transfer modules TM are referred to as a left-row process module group, and the process modules PM installed on the right side of the respective transfer module TM are referred to as a right-row process module group. The left-row process module group and the right-row process module group extend parallel to the transfer module group.

The left-row process module group includes a first process module PM1, a third process module PM3, a fifth process module PMS, and a seventh process module PM7 in order from the near side to the far side of the load lock module LLM. The right row process module group includes a second process module PM2, a fourth process module PM4, a sixth process module PM6, and an eighth process module PM8 in order from the near side to the far side of the load lock module LLM.

The first process module PM1 is disposed on the left side and in the middle of the first transfer module TM1 and the second transfer module TM2, and is connected to the first transfer module TM1 and the second transfer module TM2. The second process module PM2 is disposed on the right side and in the middle of the first transfer module TM1 and the second transfer module TM2, and is connected to the first transfer module TM1 and the second transfer module TM2.

The third process module PM3 is disposed on the left side and in the middle of the second transfer module TM2 and the third transfer module TM3, and is connected to the second transfer module TM2 and the third transfer module TM3. The fourth process module PM4 is disposed on the right side and in the middle of the second transfer module TM2 and the third transfer module TM3, and is connected to the second transfer module TM2 and the third transfer module TM3.

The fifth process module PM5 is disposed on the left side and in the middle of the third transfer module TM3 and the fourth transfer module TM4, and is connected to the third transfer module TM3 and the fourth transfer module TM4. The sixth process module PM6 is disposed on the right side and in the middle of the third transfer module TM3 and the fourth transfer module TM4, and is connected to the third transfer module TM3 and the fourth transfer module TM4.

The seventh process module PM7 is disposed on the left side of the fourth transfer module TM4 and connected to the fourth transfer module TM4. The eighth process module PM8 is disposed on the right side of the fourth transfer module TM4 and is connected to the fourth transfer module TM4.

Each of the transfer modules TM includes a transfer robot 32. Each transport module TM is formed in a hexagonal box shape in plan view. Two load lock modules LLM, the first process module PM1, and the second process module PM2 are connected to the first transfer module TM1. The first process module PM1 to the fourth process module PM4 are connected to the second transfer module TM2. The third process module PM3 to the sixth process module PM6 are connected to the third transfer module TM3. The fifth process module PM5 to the eighth process module PM8 are connected to the fourth transfer module TM4.

The transfer robot 32 is configured to be movable in the horizontal direction and the vertical direction and rotatable in the horizontal direction, and includes a fork for horizontally holding the substrate W during transfer. The transfer robot 32 provided in each of the first transfer module TM1 to the fourth transfer module TM4 can be operated independently of each other under the control of the control device 80. The transfer robot 32 transfers and receives the substrate W by moving forward and backward with respect to the two load lock modules LLM and the first process module PM1 to the eighth process module PM8.

With respect to the above, each of the multiple process modules PM accommodates the substrate W therein and performs substrate processing on the substrate W. The process module PM is formed in a polygonal shape (a pentagonal shape) in plan view. Between each transfer module TM and a corresponding process module PM, the gate valve 16, which communicates with spaces of the transfer module TM and the process module PM and through which the substrate W is caused to pass, is individually provided.

Among the process modules PM, in the process module PM1 (the substrate processing apparatus PM1) to which the substrate W is first transferred from the load lock module LLM, the substrate processing method illustrated in FIG. 4 is performed and the degassing process is performed. Thereby, in the process module PM1 (the substrate processing apparatus PM1), an impurity such as moisture is removed from the surface of the substrate W. During the degassing process, the occurrence of abnormal discharge between the electrodes 13 can be prevented by the discharge

The substrate W from which the impurity has been removed in the process module PM1 (the substrate processing apparatus PM1) is transferred to one or more other process modules PM via the first transfer module TM1 and the like. In the one or more process modules PM, the substrate processing such as a film deposition process, an etching process, an asking process, a cleaning process, and the like is performed on the substrate W. After the degassing process is performed in the first process module PM1, the substrate processing performed in each process module PM or any one or more process modules PM of the second process module PM2 to the eighth process module PM8 may be different substrate processing or the same substrate processing. After the processing is complete, the substrate W is returned to the FOUP via the load lock module LLM and the loader 52.

Here, the substrate processing system 1 illustrated in FIG. 5 is an example, and it is needless to say that there are various system configuration examples according to applications or purposes. For example, the process modules may be two process modules: the first process module PM1 and the second process module PM2, and the transfer module TM may be one transfer module: the first transfer module TM1 adjacent to the process module PM.

As described above, according to the substrate processing method and the substrate processing apparatus of the present embodiment, abnormal discharge can be prevented from occurring between the electrodes 13 in the vacuum chamber 10 based on Paschen's law.

It should be considered that the substrate processing method and the substrate processing apparatus according to the embodiments disclosed herein are examples in all respects and are not restrictive. The embodiments can be modified and improved in various forms without departing from the scope and spirit of the appended claims. The matters described in the multiple embodiments above can also be configured in other configurations as long as there is no contradiction, and can be combined as long as there is no contradiction.

In the present specification, as an example of the substrate processing apparatus PM1, a configuration example of the degassing apparatus that thermally removes an impurity on a substrate has been described. However, the substrate processing apparatus of the present disclosure is not limited to the degassing apparatus, and can be applied to a substrate processing apparatus including a heater in a stage. In the substrate processing apparatus including the heater in the stage, substrate processing such as a film deposition process or an etching process may be performed.

The substrate processing apparatus of the present disclosure can be applied to any of a single-wafer apparatus that processes substrates one by one, and a batch apparatus and a semi-batch apparatus that process multiple substrates at a time.

According to an aspect of the present invention, abnormal discharge in an electrode connected to a stage in a vacuum chamber can be prevented.

What is claimed is:

1. A substrate processing method performed by a substrate processing apparatus including: a vacuum chamber; a stage disposed in the vacuum chamber, the stage including a heater; a gas supply configured to supply a gas into the vacuum chamber;
an exhaust device configured to exhaust the gas in the vacuum chamber; and an electrode installed in the vacuum chamber, the electrode being connected to the stage and applying a voltage to the heater, the substrate processing method comprising:
performing a discharge countermeasure process including:
lowering the voltage applied to the heater while a pressure in the vacuum chamber is within a discharge pressure range, the discharge pressure range being determined based on Paschen's law as a pressure range in which discharge occurs in the vacuum chamber; and
applying the voltage to the heater in response to determining that the pressure in the vacuum chamber is out of the discharge pressure range.

2. The substrate processing method as claimed in claim 1, wherein the lowering of the voltage includes applying a low voltage, the low voltage being lower than the voltage applied to the heater immediately prior thereto and being at a level at which abnormal discharge does not occur.

3. The substrate processing method as claimed in claim 2, wherein an upper limit of the low voltage is 100 V.

4. The substrate processing method as claimed in claim 1, wherein a gas atmosphere in the vacuum chamber is an atmosphere of an argon gas.

5. A substrate processing method performed by a substrate processing apparatus including: a vacuum chamber; a stage disposed in the vacuum chamber, the stage including a heater; a gas supply configured to supply a gas into the vacuum chamber;
an exhaust device configured to exhaust the gas in the vacuum chamber; and an electrode installed in the vacuum chamber, the electrode being connected to the stage and applying a voltage to the heater, the substrate processing method comprising:
performing a discharge countermeasure process including:
applying the voltage to the heater;
switching the gas supplied into the vacuum chamber from an argon gas to a nitrogen gas and supplying the nitrogen gas into the vacuum chamber while a pressure in the vacuum chamber is within a discharge pressure range, the discharge pressure range being determined based on Paschen's law as a pressure range in which discharge occurs in the vacuum chamber; and
switching from the nitrogen gas to the argon gas and supplying the argon gas into the vacuum chamber again in response to determining that the pressure in the vacuum chamber is out of the discharge pressure range.

6. The substrate processing method as claimed in claim 1, wherein it is determined whether to perform the discharge countermeasure process, based on the Paschen's law by using a type of the gas supplied into the vacuum chamber, the pressure in the vacuum chamber, and the voltage applied to the heater.

7. A substrate processing apparatus comprising:
a vacuum chamber;
a stage disposed in the vacuum chamber, the stage including a heater;
a gas supply configured to supply a gas into the vacuum chamber;
an exhaust device configured to exhaust the gas in the vacuum chamber;
an electrode installed in the vacuum chamber, the electrode being connected to the stage and applying a voltage to the heater; and
a controller,
wherein the controller controls a discharge countermeasure process including:
lowering the voltage applied to the heater while a pressure in the vacuum chamber is within a discharge pressure range, the discharge pressure range being determined based on Paschen's law as a pressure range in which discharge occurs in the vacuum chamber,; and
applying the voltage to the heater in response to determining that the pressure in the vacuum chamber is out of the discharge pressure range.

8. The substrate processing method as claimed in claim 1, wherein the lowering of the voltage includes stopping of applying the voltage to the heater.
